(19) United States
(12) Patent Application Publication
(10) Pub. No.: US 2026/0123070 A1
(43) Pub. Date: Apr. 30, 2026

(54) IMAGE SENSOR AND FABRICATION METHOD THEREOF

(71) Applicant: SAMSUNG ELECTRONICS CO., LTD., Suwon-si (KR)

(72) Inventors: Seunghwi YOO, Suwon-si (KR); Kook Tae KIM, Suwon-si (KR); Miseon PARK, Suwon-si (KR); Minkyung LEE, Suwon-si (KR); Sangkyu JEONG, Suwon-si (KR)

(73) Assignee: SAMSUNG ELECTRONICS CO., LTD., Suwon-si (KR)

(21) Appl. No.: 19/255,036

(22) Filed: Jun. 30, 2025

(30) Foreign Application Priority Data
Oct. 28, 2024 (KR) 10-2024-0148728

(51) Int. Cl. H10F 39/00; H10F 39/18

(52) U.S. Cl. CPC H10F 39/80373; H10F 39/182

(57) ABSTRACT

An image sensor includes a substrate, a gate insulating layer on the substrate, at least one gate on the gate insulating layer, a diffusion barrier layer on an upper surface of the at least one gate and including a silicon oxynitride, and a capping insulating layer on the diffusion barrier layer, and wherein the gate includes a nitrogen-rich gate region adjacent to the upper surface of the gate therein, and the nitrogen-rich gate region has a higher content of nitrogen than the remaining region in the gate excluding the nitrogen-rich gate region.

### CROSS-REFERENCE TO RELATED APPLICATION(S)

This U.S. non-provisional application claims priority under 35 USC § 119 to Korean Patent Application No. 10-2024-0148728, filed on Oct. 28, 2024, in the Korean Intellectual Property Office, the disclosure of which is herein incorporated by reference in its entirety.

### BACKGROUND

The present invention relates to an image sensor and a fabrication method thereof.

Image sensors convert optical images into electrical signals. Recently, with the development of the computer and communication industries, the demand for image sensors with improved performance has increased in various fields such as digital cameras, camcorders, personal communication systems (PCSs), gaming devices, security cameras, and medical micro cameras. The image sensor is configured by arranging a plurality of unit pixels in an array form. Generally, the unit pixel may be composed of one photodiode and a plurality of pixel transistors. Here, the pixel transistors may include, for example, a transfer transistor, a reset transistor, a source follower transistor, and a selection transistor. The performance of the pixel transistors affects the quality of the image element.

### SUMMARY

The present invention is directed to providing an image element including pixel transistors with improved performance.

An image sensor according to one embodiment of the present invention may include a substrate, a gate insulating layer on the substrate, at least one gate on the gate insulating layer, a diffusion barrier layer on an upper surface of the at least one gate and including a silicon oxynitride, and a capping insulating layer on the diffusion barrier layer, and wherein the gate may include a nitrogen-rich gate region adjacent to the upper surface of the gate therein, and the nitrogen-rich gate region may have a higher content of nitrogen than the remaining region in the gate excluding the nitrogen-rich gate region.

The diffusion barrier layer may have a thickness of 1 Å to 60 Å.

The gate may include doped polysilicon.

The image sensor may further include an etching stop layer between the diffusion barrier layer and the capping insulating layer, and wherein the etching stop layer may include a silicon oxide and the capping insulating layer includes a silicon nitride.

The image sensor may further include a capping liner on both side surfaces of the at least one gate in a cross-sectional view.

The diffusion barrier layer may extend onto both side surfaces of the at least one gate in a cross-sectional view.

The image sensor may further include a deep isolation pattern penetrating through the substrate, a shallow isolation pattern defining an active region, and at least one pixel transistor in and/or on the active region, and wherein the at least one gate is a gate of the at least one pixel transistor.

The at least one pixel transistor may include a transfer transistor, a source follower transistor, a selection transistor, and a reset transistor, and the at least one gate may be at least one among gates of the transfer transistor, the source follower transistor, the selection transistor, and the reset transistor.

The gate of the transfer transistor may be provided in a vertical type, and the gates of the source follower transistor, the selection transistor, and the reset transistor may be provided in a planar type.

The at least one pixel transistor may be a fin field effect transistor (finFET) transistor.

The at least one gate may include a lower gate on the gate insulating layer and an upper gate on the lower gate.

An image sensor according to one embodiment of the present invention may include a substrate having a first surface and a second surface opposite to the first surface, a deep isolation pattern penetrating through the substrate to define a plurality of pixel regions, a shallow isolation pattern disposed adjacent to the first surface to define a plurality of active regions in the plurality of pixel regions, a floating diffusion region disposed in the active region, a source follower gate disposed on the active region, a diffusion barrier layer on the source follower gate and including a silicon oxynitride, and a capping insulating layer on the diffusion barrier layer, and wherein the diffusion barrier layer may have a thickness of 1 Å to 60 Å.

The source follower gate may include a nitrogen-rich gate region adjacent to an upper surface of the source follower gate therein, and the nitrogen-rich gate region may have a higher content of nitrogen than the remaining region in the source follower gate excluding the nitrogen-rich gate region.

The image sensor may further include an etching stop layer between the diffusion barrier layer and the capping insulating layer, and wherein the etching stop layer may include a silicon oxide, and the capping insulating layer may include a silicon nitride.

A fabrication method of an image sensor according to one embodiment of the present invention may include forming a gate insulating layer on a substrate including a plurality of pixel regions, forming a gate layer on the gate insulating layer, performing a plasma nitridation process on the gate layer, performing post-nitridation anneal on the gate layer on which the plasma nitridation process has been performed to form a diffusion barrier layer, patterning the gate layer to form at least one gate corresponding to the pixel regions, and forming a capping insulating layer on the diffusion barrier layer.

The fabrication method may further include, after the patterning of the gate layer, oxidizing both side surfaces of the gate to form a capping liner.

The fabrication method may further include, after the patterning of the gate layer, performing the plasma nitridation process on both side surfaces of the gate and performing the post-nitridation anneal on both side surfaces of the gate on which the plasma nitridation process has been performed.

The forming of the gate layer may include forming a polysilicon layer on the substrate, and doping an impurity into the polysilicon layer.

The forming of the gate layer may include forming a lower gate layer on the substrate, doping an impurity into the lower gate layer, forming an upper gate layer on the lower gate layer, and doping an impurity into the upper gate layer.

The fabrication method may further include, before the forming of the capping insulating layer, forming a first etching stop layer on the diffusion barrier layer, forming a gate spacer on both side surfaces of the gate on the etching stop layer, and forming a second etching stop layer on the gate spacer.

An image sensor according to one embodiment of the present invention may include a substrate, a gate insulating layer disposed on the substrate, a gate disposed on the gate insulating layer and including a nitrogen-rich gate region having a higher content of nitrogen than another region in the gate, a diffusion barrier layer disposed on the gate and including a silicon oxynitride, and a capping insulating layer disposed on the diffusion barrier layer, and a contact plug penetrating through the capping insulating layer, the diffusion barrier layer, and the nitrogen-rich gate region.

The image sensor may further include an etching stop layer between the diffusion barrier layer and the capping insulating layer. The etching stop layer may include a silicon oxide and the capping insulating layer includes a silicon nitride, and the contact plug also penetrates through the etching stop layer.

The contact plug may penetrate in the another region in the gate having a lower content of nitrogen than the nitrogen-rich gate region.

The gate may include a lower gate on the gate insulating layer and an upper gate on the lower gate, and the contact plug may penetrate in the lower gate.

The diffusion barrier layer may extend onto side surfaces of the gate.

### BRIEF DESCRIPTION OF DRAWINGS

FIG. 1 is a block diagram of an image sensor according to some embodiments of the present disclosure.

FIG. 2 is a circuit diagram of pixels included in a pixel array of an image sensor according to one embodiment of the present disclosure.

FIG. 3 is a plan view exemplarily showing one pixel group of an image sensor according to exemplary embodiments.

FIG. 4A is a cross-sectional view taken along line A-A′ of FIG. 3, and FIG. 4B is a cross-sectional view taken along line B-B′ of FIG. 3.

FIG. 5 is an enlarged cross-sectional view showing a region in which a source follower gate is formed in an image sensor according to one embodiment.

FIGS. 6A to 6K are cross-sectional views sequentially showing a fabrication method of an image sensor according to one embodiment of the present invention.

FIG. 7 is an enlarged cross-sectional view showing a region in which a source follower gate is formed in an image sensor according to one embodiment.

FIGS. 8A to 8M are cross-sectional views sequentially showing a fabrication method of an image sensor according to one embodiment of the present invention.

FIG. 9 is an enlarged cross-sectional view showing a region in which a source follower gate is formed in an image sensor according to one embodiment.

FIG. 10 is an enlarged cross-sectional view showing a region in which a transfer gate is formed in an image sensor according to one embodiment.

FIGS. 11A to 11D are enlarged cross-sectional views showing regions in which gates of pixel transistors are formed in an image sensor according to one embodiment of the present invention.

### DETAILED DESCRIPTION

Hereinafter, embodiments of the present invention will be described in detail with reference to the accompanying drawings.

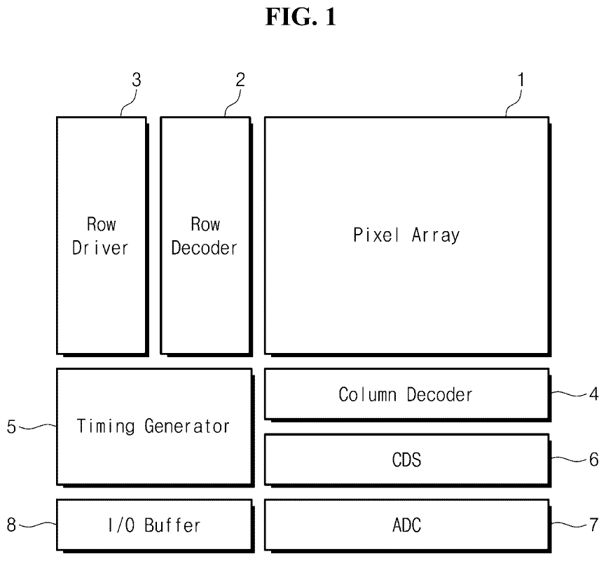

FIG. 1 is a block diagram of an image sensor according to some embodiments of the present disclosure.

Referring to FIG. 1, the image sensor according to some embodiments of the present invention may include a pixel array 1, a row decoder 2, a row driver 3, a column decoder 4, a timing generator 5, a correlated double sampler (CDS) 6, an analog to digital converter (ADC) 7, and an input/output buffer (I/O buffer) 8.

The pixel array 1 may include a plurality of pixels arranged two-dimensionally, and the pixels may convert optical signals into electrical signals. The pixel array 1 may be driven by a plurality of driving signals (e.g., a pixel selection signal, a reset signal, and/or a charge transfer signal) transmitted from the row driver 3. The converted electrical signals may be provided to the CDS 6.

The row driver 3 may provide the plurality of driving signals for driving the plurality of pixels based on decoded results from the row decoder 2 to the pixel array 1. When the pixels are arranged in a matrix form, the driving signals may be provided in a row unit.

The timing generator 5 may provide a timing signal and a control signal to the row decoder 2 and the column decoder 4.

The CDS 6 may receive the electrical signals generated from the pixel array 1 and may hold and sample the received signals. The CDS 6 may double-sample a specific noise level and a signal level caused by an electrical signal to output a difference level corresponding to the difference between the noise level and the signal level.

The ADC 7 may convert an analog signal corresponding to the difference level output from the CDS 6 into a digital signal and may output the digital signal.

The I/O buffer 8 may latch the digital signals and sequentially output the latched signals to an image signal processor (not shown) based on the decoded results from the column decoder 4.

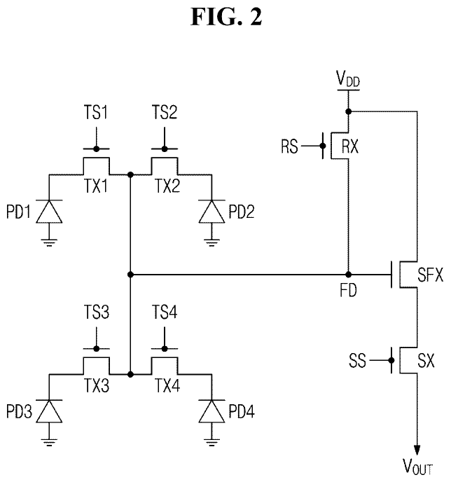

FIG. 2 is a circuit diagram of pixels included in a pixel array of an image sensor according to one embodiment of the present disclosure.

Referring to FIG. 2, a pixel array may include a plurality of pixel groups, each of the pixel groups may include a plurality of pixels. In one embodiment, each of the pixel groups may include a first pixel, a second pixel, a third pixel, and a fourth pixel. The first to fourth pixels may respectively include first to fourth photodiodes PD1, PD2, PD3 and PD4, transfer transistors TX1, TX2, TX3, and TX4, and logic transistors. The logic transistors may include a reset transistor RX, a selection transistor SX, and a source follower transistor SFX. Gates of the first to fourth transfer transistors TX1, TX2, TX3, and TX4 may be respectively connected to first to fourth transfer gate lines TS1, TS2, TS3, and TS4. The first to fourth pixels may share the reset transistor RX, the source follower transistor SFX, and the selection transistor SX.

Each of the first to fourth photodiodes PD1, PD2, PD3, and PD4 may generate and accumulate photocharges in proportion to amount of light incident from the outside. In one embodiment, each of the first to fourth photodiodes PD1, PD2, PD3, and PD4 may include a phototransistor, a photogate, a pinned photodiode, or a combination thereof. The first to fourth transfer transistors TX1, TX2, TX3, and TX4 may transfer the photocharges generated from the first to fourth photodiodes PD1, PD2, PD3, and PD4 to the floating diffusion region FD. The floating diffusion region FD may receive and cumulatively store the photocharges generated from the first to fourth photodiodes PD1, PD2, PD3, and PD4.

A gate of the source follower transistor SFX may be connected to the floating diffusion region FD. A drain terminal of the source follower transistor SFX may be connected to a power terminal V_{DD} that may receive a power voltage. The source follower transistor SFX may be controlled according to the amount of the photocharges accumulated in the floating diffusion region. The source follower transistor SFX may convert a signal corresponding to the amount of the input photocharges into a voltage signal.

The reset transistor RX may periodically reset charges accumulated in the floating diffusion region. A gate of the reset transistor RX may be connected to a reset gate line RS. A source terminal of the reset transistor RX may be connected to the floating diffusion region FD, and a drain terminal of the reset transistor RX may be connected to the power terminal V_{DD}. When the reset transistor RX is turned on, the power voltage of the power terminal V_{DD} may be applied to the floating diffusion region through the reset transistor Rx. In other words, when the reset transistor RX is turned on, the charges accumulated in the floating diffusion region FD may be discharged by the power voltage, thereby resetting the floating diffusion region FD.

The source follower transistor SFX may serve as a source follower buffer amplifier. The source follower transistor SFX may amplify a potential change in floating diffusion region FD and output the amplified potential change to an output line V_{OUT}.

A gate of the selection transistor SX may be connected to a selection gate line SS. A drain terminal of the selection transistor SX may be connected to a source terminal of the source follower transistor DX, and a source terminal of the selection transistor SX may be connected to the output line V_{OUT}. The selection transistors SX of the pixels PX to be readout in a row unit may be selected by a selection signal applied through the corresponding selection gate line SS. When the selection transistor SX is turned on, the potential change amplified by the source follower transistor SFX may be output to the output line V_{OUT} through the selection transistor SX.

In the embodiments of FIG. 2, the pixel group includes the four pixels, but this is for convenience of explanation, and the embodiments of the present disclosure are not limited thereto. The number of pixels of the pixel group may be variously changed. For example, the number of pixels of the pixel group may be two, eight, or nine. In one embodiment, the pixel group may also include a single pixel. In some embodiments, the pixels in one pixel group may share one or more components. For example, the pixels in one pixel group may share the floating diffusion region FD and may share at least one of the logic transistors RX, SX, and SFX.

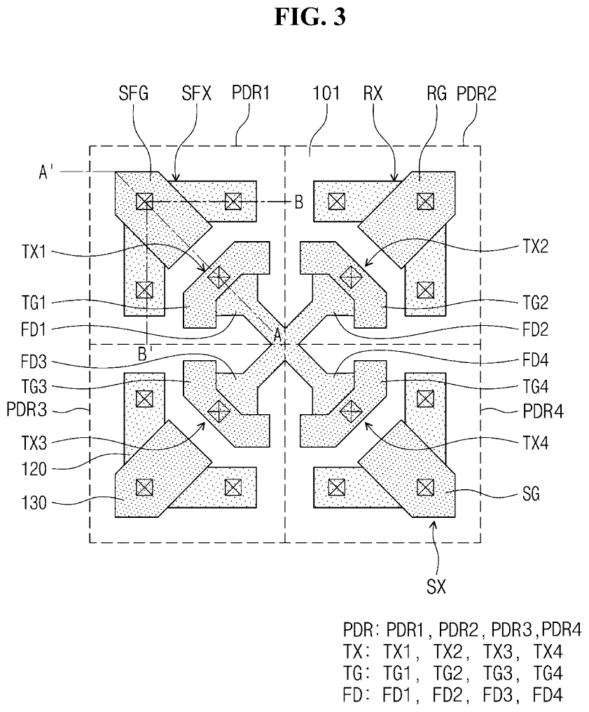

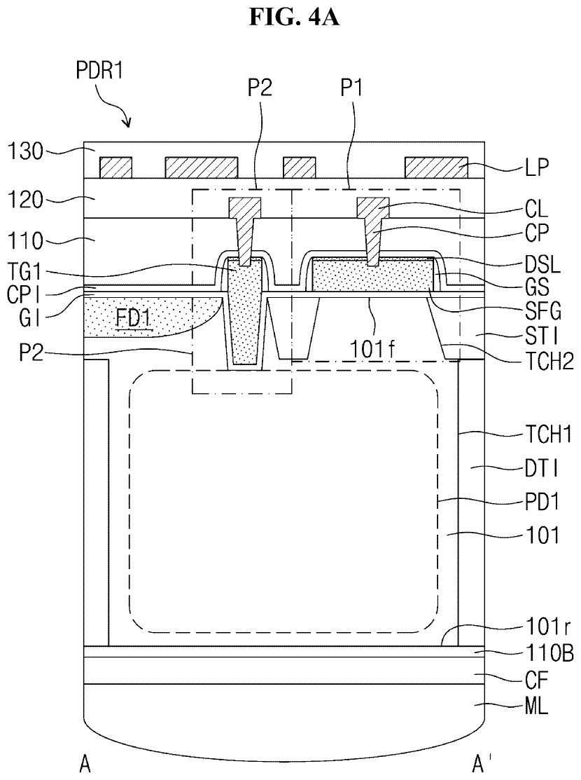

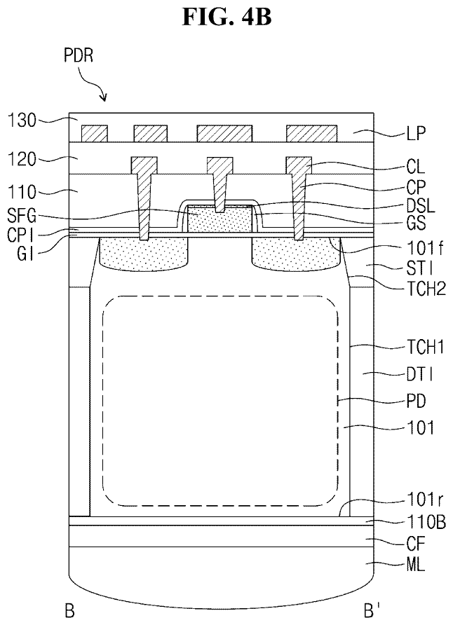

FIG. 3 is a plan view exemplarily showing one pixel group of an image sensor according to exemplary embodiments and shows an image sensor that implements the circuit diagram of FIG. 2. FIG. 4A is a cross-sectional view taken along line A-A′ of FIG. 3, and FIG. 4B is a cross-sectional view taken along line B-B′ of FIG. 3.

Referring to FIGS. 2, 3, 4A, and 4B, in one embodiment of the present invention, one pixel group may include first to fourth photodiode regions PDR1, PDR2, PDR3, and PDR4 arranged in a 2×2 matrix format as shown. The first to fourth photodiode regions PDR1, PDR2, PDR3, and PDR4 each include the photodiode region PDR or FD1, FD2, FD3, and FD4, the floating diffusion region FD or FD1, FD2, FD3, and FD4, and the transfer transistor TX or TX1, TX2, TX3, and TX4. That is, a first photodiode region PDR1 may include a first photodiode PD1, a first floating diffusion region FD1, and a first transfer transistor TX1, a second photodiode region PDR2 may include a second photodiode PD2 (not shown), a second floating diffusion region FD2, and a second transfer transistor TX2, a third photodiode region PDR3 may include a third photodiode PD3 (not shown), a third floating diffusion region FD3, and a third transfer transistor TX3, and a fourth photodiode region PDR4 may include a fourth photodiode PD4 (not shown), a fourth floating diffusion region FD4, and a fourth transfer transistor TX4. The first to fourth floating diffusion regions FD1, FD2, FD3, and FD4 may be connected to each other to be one floating diffusion region FD and may be shared by the first to fourth photodiode regions PDR1, PDR2, PDR3, and PDR4.

In addition, one pixel group may include the reset transistor RX, the source follower transistor SFX, and the selection transistor SX. The reset transistor RX, the source follower transistor SFX, and the selection transistor SX may each be provided in any one of the first to fourth photodiode regions PDR1, PDR2, PDR3, and PDR4. For example, the source follower transistor SFX may be provided in the first photodiode region PDR1, the reset transistor RX may be provided in the second photodiode region PDR2, and the selection transistor SX may be provided in the fourth photodiode region PDR4. In addition, although not shown, one or more ground regions may be provided for each pixel in one pixel group. However, the arrangement of lines including transistors in one pixel group is not limited thereto and may be formed differently.

The first to fourth transfer transistors TX or TX1, TX2, TX3, and TX4 may include first to fourth transfer gates TG or TG1, TG2, TG3, and TG4 that form transfer channels between the photodiode regions PDR and the first to fourth floating diffusion regions FD or FD1, FD2, FD3, and FD4. The first to fourth transfer gates TG or TG1, TG2, TG3, and TG4 may have a vertical type (or a buried type) gate structure.

In addition, the image sensor may include a deep isolation pattern DTI, a shallow isolation pattern STI, first to third interlayer insulating layers 110, 120, and 130, a contact complex CA, line patterns LP, color filters CF, and microlenses ML that are formed in and/or on the substrate 101.

The substrate 101 may include a first surface 101f and a second surface 101r that are opposite to each other. In the present specification, the first surface 101f may be referred to as a front surface, and the second surface 101r may be referred to as a back surface. The second surface 101r may be a light incident surface. Here, for convenience, a surface of the substrate 101 on which the color filter CF is disposed on an upper portion thereof is referred to as the second surface 101r, and a surface opposite to the second surface 101r is referred to as the first surface 101f.

The substrate 101 may be a silicon (Si) substrate, a germanium (Ge) substrate, a silicon-germanium (Si—Ge) substrate, a group II-VI compound semiconductor substrate, a group III-V compound semiconductor substrate, or a silicon on insulator (SOI) substrate. The substrate 101 may include an impurity of a first conductivity type, and accordingly, the substrate 101 may have the first conductivity type. For example, the impurities of the first conductivity type may be a group III element. For example, the impurities of the first conductivity type may include P-type impurities such as aluminum (Al), boron (B), indium (In), and/or gallium (Ga).

The photodiode region PDR may be provided in the substrate 101. The photodiode region PDR may include impurities having a second conductivity type different from the first conductivity type, and accordingly, the photodiode region PDR may have the second conductivity type. For example, the impurities of the second conductivity type may be a group V element. For example, the impurities of the second conductivity type may include N-type impurities such as phosphorus, arsenic, bismuth, and/or antimony.

The substrate 101 and the photodiode region PDR may configure the above-described photodiode PD by being P-N junctioned with each other.

In one embodiment, the deep isolation pattern DTI may be provided in the substrate 101 to define photodiode regions PDR in the substrate 101, and at least one photodiode region PDR may be provided in each of the photodiode regions PDR.

A deep isolation pattern DTI may penetrate through the substrate 101. For example, the deep isolation pattern DTI may penetrate through the first and second surfaces 101f and 101r of the substrate 101 and a body of the substrate 101 between the first and second surfaces 101f and 101r of the substrate 101.

The deep isolation pattern DTI may be formed in the substrate 101 to surround each of the photodiode regions PDR from a plan view. The deep isolation pattern DTI penetrates at least a part of the substrate 101 from the first surface 101f. The deep isolation pattern DTI may be implemented with a trench or a doped layer. The expression “penetrating at least a part of the substrate from the first surface 101f” used to describe the deep isolation pattern DTI does not limit the directional aspect of the semiconductor process that forms the trench or the doping layer, but rather refers to the shape of the final structure after the deep isolation pattern DTI has been formed. For example, the phrase “A trench penetrates at least a part of the substrate from the first surface” does not restrict the trench to being formed from the first substrate, but instead means that the structure penetrates from the first surface to another direction or from another direction toward to the first surface. This also includes structures where a trench penetrates from a second surface, opposite to the first surface, toward the first surface. The deep isolation pattern DTI may be formed using a technology of filling an insulating material in a deep trench TCH1 formed by patterning the substrate 101, that is, a deep trench isolation technology. In one embodiment, the photodiode region PDR may be a portion of the substrate 101 surrounded by the deep isolation pattern DTI.

In one embodiment, the deep isolation pattern DTI may include a conductive isolation layer provided in the deep trench TCH1 and an insulating liner provided between the substrate 101 and the conductive isolation layer. The conductive isolation layer may include a conductive material such as a doped semiconductor material (e.g., doped polysilicon). The conductive isolation layer may be spaced apart from the substrate 101 by the insulating liner, and accordingly, during the operation of the image sensor, the conductive isolation layer may be electrically isolated from the substrate 101.

The shallow isolation pattern STI may be disposed in a shallow trench TCH2 recessed by a predetermined depth from the first surface 101f of the substrate 101.

The shallow isolation pattern STI may define active regions in the substrate 101. The shallow isolation pattern STI may be provided between the active regions to electrically isolate the active regions in the substrate 101. In one embodiment, the shallow isolation pattern STI may define at least one active region in each of the photodiode regions PDR.

In one embodiment, the deep isolation pattern DTI may partially overlap the shallow isolation pattern STI. An overlapping portion of the deep isolation pattern DTI and the shallow isolation pattern STI may correspond to a portion of the shallow isolation pattern STI or a portion of the deep isolation pattern DTI. The shallow trench TCH2 may extend laterally in a plan view to intersect the deep isolation pattern DTI. In this case, a bottom surface of the shallow trench TCH2 may come into contact with an upper surface of the deep isolation pattern DTI.

Each of the first to fourth transfer gates TG or TG1, TG2, TG3, and TG4 may be disposed on the first surface 101f of the substrate 101. Each transfer gate TG may be disposed on the corresponding active region of each of the photodiode regions PDR. A gate insulating layer GI may be disposed between each transfer gate TG and the active region. In one embodiment, the shallow trench TCH2 may be formed in the shallow isolation pattern STI of both sides of a portion of the active region, and the shallow trench TCH2 may expose both side surfaces of the portion of the active region. Each transfer gate TG may be disposed on an upper surface of the portion of the active region and in the active region. In one embodiment, the gate insulating layer GI may extend to be disposed between each transfer gate TG and an inner surface of the active region. More specifically, each transfer gate TG may include a vertical portion covering the exposed both side surfaces of the active region and an upper portion covering the upper surface of the portion of the active region. Accordingly, a channel region defined in the active region under each transfer gate TG may include a pair of vertical channel portions that are each adjacent to one of the exposed both side surfaces of the active region and a horizontal channel portion adjacent to the upper surface of the portion of the active region.

The floating diffusion regions FD including the first to fourth floating diffusion regions FD1, FD2, FD3, and FD4, may be provided in the active region of one side of the transfer gate TG. In one embodiment, the floating diffusion region FD may be a region doped with impurities of the second conductivity type.

Although not shown, the ground region may be provided in the active region of the photodiode regions PDR. In one embodiment, the ground region may be a region doped with impurities of the first conductivity type. In other words, the ground region may have the same conductivity type as the substrate 101. The ground region may receive a ground voltage.

Diffusion barrier layers DSL may be provided on an upper surface of each transfer gate TG. The diffusion barrier layers DSL may include an insulating material different from that of the gate insulating layer GI. For example, the diffusion barrier layers DSL may include a silicon oxynitride (SiON). A content of nitrogen in the diffusion barrier layers DSL may correspond to about 40 at % to about 60 at %, for example, about 45 at %, of a content of nitrogen in a silicon nitride (Si₃N₄) of the same thickness. For example, the expression being “about” a value may refer to being exactly the value, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

Gate spacers GS may be provided on side surfaces of each transfer gate TG. In one embodiment, the gate spacers GS may include an insulating material different from that of the shallow isolation pattern STI. For example, when the shallow isolation pattern STI includes a silicon oxide, the gate spacers GS may include a silicon nitride and/or a silicon oxynitride.

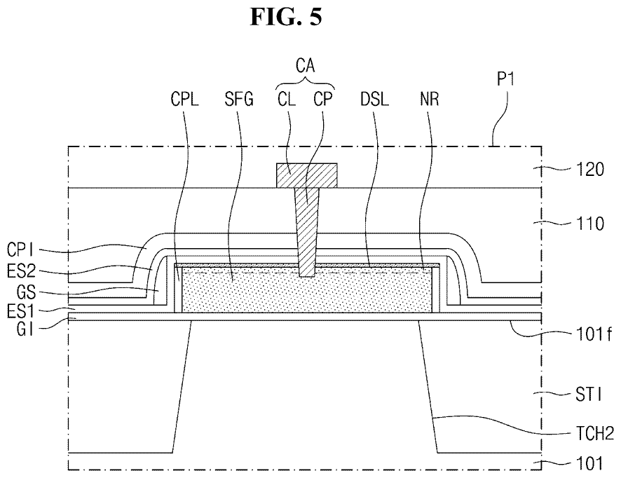

In one embodiment, a capping liner CPL, a first etching stop layer ES1, a second etching stop layer ES2, and a capping insulating layer CPI may be provided between the transfer gate TG and the gate spacer GS, and on the gate spacer GS, which will be described below with reference to FIG. 5.

Referring back to FIGS. 2, 3, 4A, and 4B, in one embodiment, the color filters CF may be arranged in a matrix form on the photodiode regions PDR corresponding to each color filter. For example, the color filters may be arranged in a 2×2 matrix form, a 3×3 matrix form, or a 4×4 matrix form according to the arrangement of the corresponding photodiode regions PDR. In some embodiments, the color filters CF may include a first color filter having a first color, a second color filter having a second color, and a third color filter having a third color. In one embodiment, the first color may be one of red, green, and blue colors, the second color may be another one of red, green, and blue colors, and the third color may be the remaining one of red, green, and blue colors. In some embodiments, when one pixel group includes the pixels arranged in a 2×2 matrix form, four color filters CF each corresponding to each pixel may be formed in a Bayer pattern. For example, two pixels of a first row may each have one of blue and green colors, and two pixels of a second row may each have one of green and red colors.

Alternatively, the first color may be one of magenta, cyan, and yellow colors, the second color may be another one of magenta, cyan, and yellow colors, and the third color may be the remaining one of magenta, cyan, and yellow colors. However, the embodiments of the present application are not limited thereto. The first to third colors may be various other colors.

In some embodiments, one pixel group may have one color, but when a plurality of pixel groups are arranged, the plurality of pixel groups may be formed entirely in a Bayer pattern. For example, when four pixel groups are arranged in a 2×2 matrix form, two pixel groups of the first row may each have one of blue and green colors, and two pixel groups of the second row may each have one of green and red colors.

In one embodiment, the microlenses ML may be disposed on the second surface 101r of the substrate 101. For example, the microlens ML may be disposed on the color filter CF. For example, the microlenses ML may be disposed on the color filters CF. Each of the microlenses ML may vertically overlap one of the photodiode regions PDR. Alternatively, in one embodiment, each of the microlenses ML shown in FIGS. 4A and 4B may vertically overlap a plurality of photodiode regions PDR that are adjacent to each other. For example, each of the microlenses ML may vertically overlap the photodiode regions PDR arranged in a 2×2 matrix form, a 3×3 matrix form, or a 4×4 matrix form. In some embodiments, the number of photodiode regions 110 overlapping at least one of the microlenses ML may differ from the number of photodiode regions 110 overlapping at least another one of the microlenses ML. For example, the at least one of the microlens ML may vertically overlap a pair of photodiode regions PDR that are adjacent to each other, and the at least another one of the microlens ML may vertically overlap a single photodiode region PDR or four or more photodiode regions PDR that are adjacent to each other. In other words, it is apparent that each pixel may correspond to one microlens, and alternatively, a plurality of pixels in one pixel group may share one microlens ML. For example, when two pixels are provided in one pixel group, the two pixels may share one microlens, and when four pixels are provided in one pixel group, the four pixels may share one microlens.

Each of the microlenses ML may have a shape that is convex upward in a cross-sectional view. In some embodiments, each of the microlenses ML may have a circular shape or an elliptical shape in a plan view. The microlenses ML may be made of a light-transmitting resin.

In one embodiment, the microlens ML may include a lens pattern and a planarized portion. The planarized portion of the microlens ML may be provided on the color filter CF and the lens pattern may be provided on the planarized portion. The lens pattern and the planarized portion may form a single body without a boundary surface therebetween. The lens pattern may include the same material as the planarized portion. In one embodiment, the planarized portion may be omitted and the lens pattern may be directly disposed on the color filter CF.

The first interlayer insulating layer 110 may be provided on the first surface 101f of the substrate 101 and disposed on the capping insulating layer CPI.

A plurality of first interlayer insulating layers 110 may be provided and the first interlayer insulating layers 110 may be sequentially stacked on the first surface 101f of the substrate 101.

The contact complex CA may include contact plugs CP and contact lines CL. The contact plugs CP and contact lines CL may be disposed in and/or on the first interlayer insulating layer 110.

In one embodiment, each transfer gate TG may be electrically connected to the corresponding one of the contact lines CL through the contact plug CP provided on the transfer gate TG. In addition, the source follower gate SFG, the reset gate RG, and the selection gate SG may each be electrically connected to the corresponding one of the contact lines CL through the contact plug CP provided on each of the source follower gate SFG, the reset gate RG, and the selection gate SG.

A back insulating layer 110B may be provided on the second surface 101r of the substrate 101. The back insulating layer 110B may cover the second surface 101r of the substrate 101 and may have a single-layered or multi-layered structure. In one embodiment, the back insulating layer 110B may include a silicon-based insulating material (e.g., a silicon compound, a silicon nitride, and/or a silicon oxynitride) and/or an insulating metal oxide.

The color filters CF may be provided on the back insulating layer 110B. In one embodiment, as shown in FIGS. 4 and 4B, the color filters CF may be disposed on the second surface 101r of the substrate 101 to each correspond to the pixels. In one embodiment, each of the color filters CF may vertically overlap the corresponding one of the photodiode regions PDR. However, the embodiments of the present application are not limited thereto. In some embodiments, each of the color filters CF may vertically overlap photodiode regions PDR that are adjacent to each other. The microlenses may be provided on the color filters.

FIG. 5 is an enlarged cross-sectional view showing a region in which a source follower gate is formed in an image sensor according to one embodiment of the present invention and is an enlarged view of portion P1 of FIG. 4A. In the following embodiments, the source follower gate SFG will be described as an example, but the present invention is not limited thereto, and the reset gate, the selection gate, and/or the transfer gate may also be provided in substantially the same structure.

Referring to FIG. 5, the source follower gate SFG may be provided on the first surface 101f of the substrate 101.

The gate insulating layer GI may be provided between the source follower gate SFG and the substrate 101. The gate insulating layer GI may include a silicon oxide or a silicon oxynitride. In one embodiment, when the gate insulating layer GI includes a silicon oxynitride, the silicon oxynitride may be included on an upper portion of a silicon oxide.

The source follower gate SFG may include polysilicon doped with an impurity. The impurity may be a group III or group V element. The source follower gate SFG may include a nitrogen-rich gate region NR in a predetermined region extending in a depth direction from the interface between the diffusion barrier layer DSL and the source follower gate SFG. In some embodiments, the nitrogen-rich gate region NR may be formed to a depth of about 30 nm or less, about 20 nm or less, or about 10 nm or less from an upper surface of the source follower gate SFG. The nitrogen-rich gate region NR may have a content of nitrogen lower than the content of nitrogen of the diffusion barrier layer DSL and have the content of nitrogen whose concentration gradually decreases in the depth direction from the upper surface of the source follower gate SFG. Here, when a content of nitrogen according to a depth of the source follower gate SFG is represented by a log scale graph, the graph of the content of nitrogen may show the highest value at the interface of the source follower gate SFG and show the content of nitrogen in a tail shape in which the concentration gradually decreases.

The nitrogen-rich gate region NR may be provided in an upper portion of the source follower gate SFG and may correspond to a region having a relatively higher concentration of nitrogen than the remaining region of the source follower gate SFG. Here, the remaining region of the source follower gate SFG may not substantially include nitrogen. The diffusion barrier layer DSL may be provided on the upper surface of the source follower gate SFG. The diffusion barrier layer DSL may include a silicon oxynitride (SiON). The silicon oxynitride in the diffusion barrier layer DSL may be included in the entirety of the diffusion barrier layer (DSL). In one embodiment, the nitrogen in the diffusion barrier layer DSL may be substantially uniformly included throughout the entire region of the diffusion barrier layer DSL.

The diffusion barrier layer DSL may have a thickness of about 1 Å to about 60 Å. In one embodiment, the diffusion barrier layer DSL may have a thickness of about 5 Å to about 50 Å, or a thickness of about 5 Å to about 30 Å.

The capping liner CPL may be provided on both side surfaces of the source follower gate SFG. The capping liner CPL may be formed on the both side surfaces of the source follower gate SFG, and an upper surface of the capping liner CPL may come into contact with a lower surface of the diffusion barrier layer DSL. The both side surfaces of the diffusion barrier layer DSL may be substantially coplanar with outer surfaces of the capping liner CPL, but the present invention is not limited thereto, and the both side surfaces of the diffusion barrier layer DSL may not be coplanar with the outer surfaces of the capping liner CPL according to process margins.

The first etching stop layer ES1 may be disposed on the first surface 101f of the substrate 101 to conformally cover the source follower gate SFG and the gate insulating layer GI. In one embodiment, the first etching stop layer ES1 may include a silicon oxide. The first etching stop layer ES1 may be formed with various thicknesses and formed, for example, about 50 Å or less.

The gate spacer GS may be provided on the first etching stop layer ES1. The gate spacer GS may be provided on the both side surfaces of the source follower gate SFG. In one embodiment, the gate spacer GS may be formed of a silicon nitride (Si₃N₄) and/or a silicon oxynitride (SiON).

The second etching stop layer ES2 conformally covering the gate insulating layer GI, the diffusion barrier layer DSL, and the gate spacer GS and the capping insulating layer CPI covering the second etching stop layer ES2 may be provided on the gate insulating layer GI, the diffusion barrier layer DSL, and the gate spacer GS.

In one embodiment, the second etching stop layer ES2 may include a silicon oxide (SiO₂). The capping insulating layer CPI may be selected from materials different from that of the second etching stop layer ES2, for example, materials with high etching selectivity with respect to the second etching stop layer ES2. In one embodiment, the capping insulating layer CPI may include a silicon nitride.

The first interlayer insulating layer 110 may be provided on the capping insulating layer CPI. The first interlayer insulating layer 110 may include various insulating materials and include, for example, tetra ethyl ortho silicate TEOS.

Various lines may be provided in and on the first interlayer insulating layer 110. For example, the contact complex CA may be provided to electrically connect the source follower gate SFG to other components. The contact complex CA may include the contact plug CP penetrating through the first interlayer insulating layer 110, the second etching stop layer ES2, the first etching stop layer ES1, and the diffusion barrier layer DSL to come into contact with the source follower gate SFG and the contact line CL formed on the first interlayer insulating layer 110.

The second and third interlayer insulating layers 120 and 130 may be stacked on the first interlayer insulating layer 110, and the various line patterns LP (see FIGS. 4A and 4B) may additionally be provided in and on each interlayer insulating layer.

According to one embodiment of the present invention, the diffusion barrier layer DSL may act as a barrier to prevent impurities in a gate layer for forming the source follower gate SFG from diffusing to the outside when a thermal treatment is performed in a subsequent process, etc. In addition, since the subsequent process is not a process in which a silicon oxide is generated as polysilicon forming the gate layer is oxidized, a thickness of the polysilicon may not decrease or may not almost decrease. As a result, by forming the diffusion barrier layer DSL, the gate layer can be preserved without loss as much as possible after the formation of the gate layer, and by maintaining the thickness of the gate layer, the gate layer can have a lower surface resistance compared to a case in which the thickness of the gate layer decreases. In addition, the loss of the impurity in the gate layer can also be prevented by the diffusion barrier layer DSL. Since the impurity in the gate layer are maintained without loss, an image element, which is free from the problem of increased threshold voltage due to impurity depletion and has improved trans-conductance characteristics, can be provided.

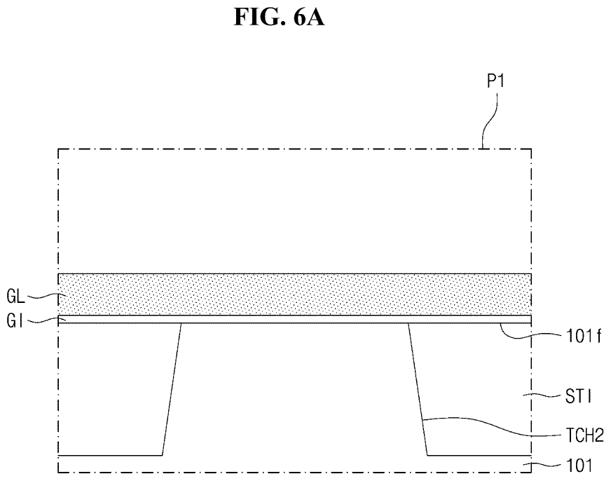

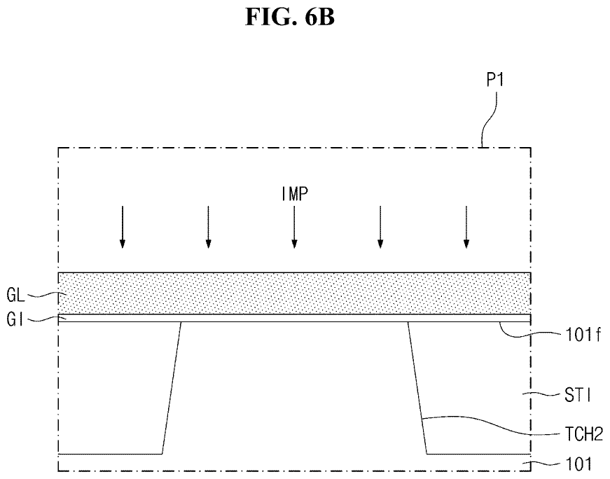

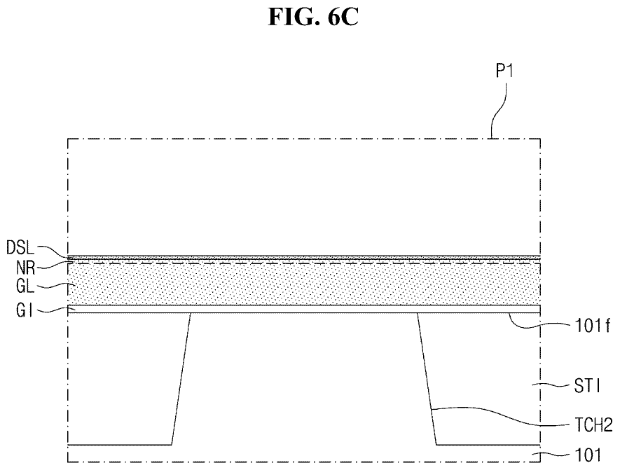

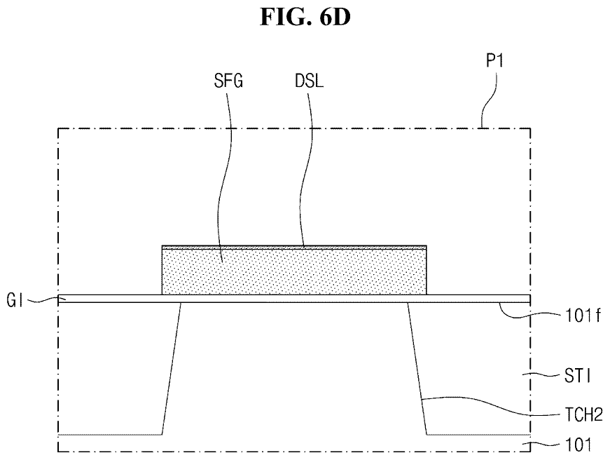

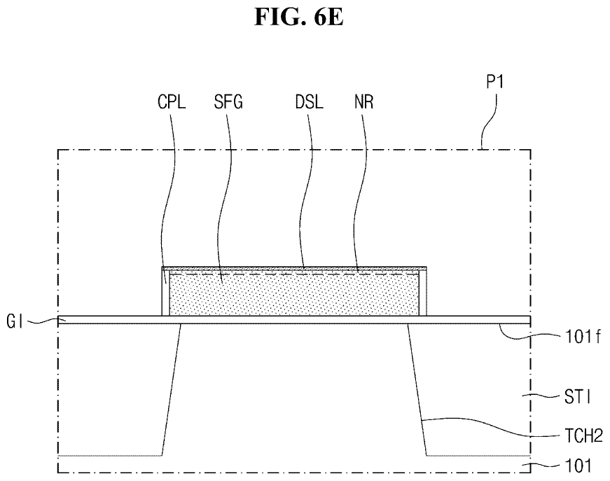

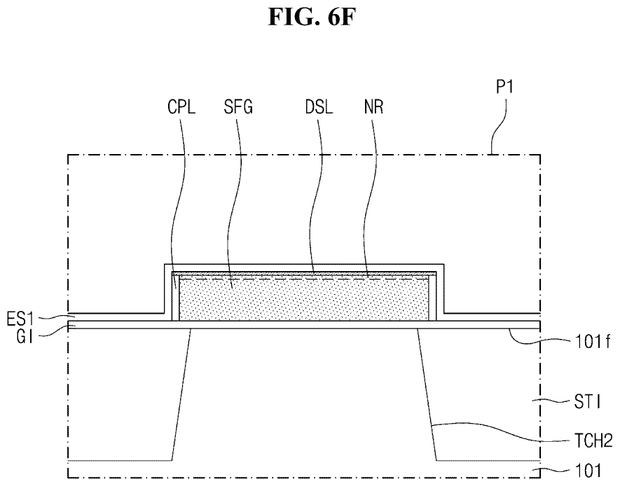

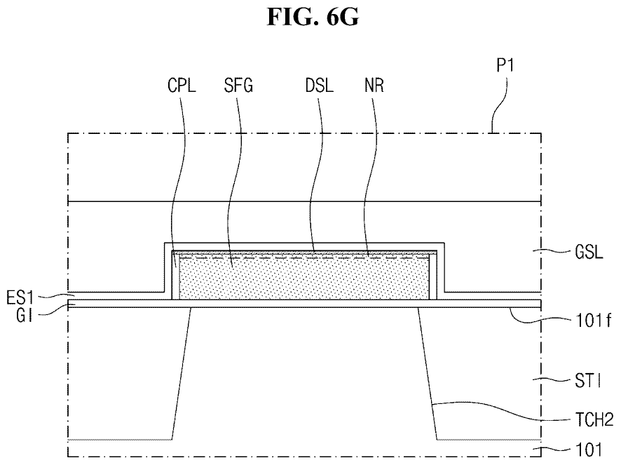

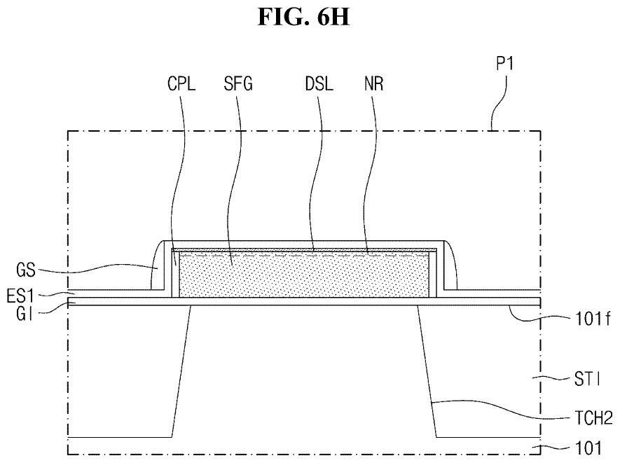

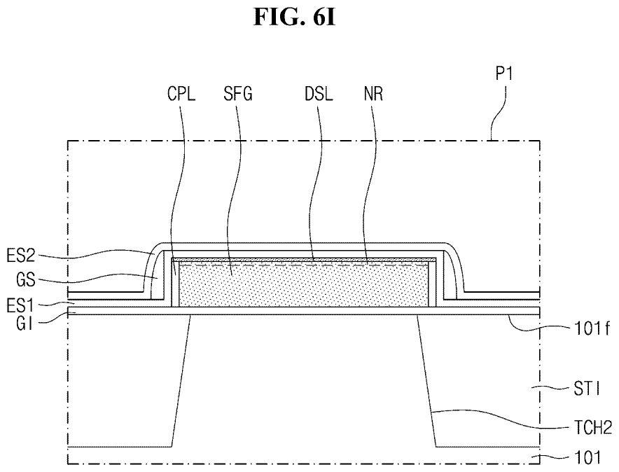

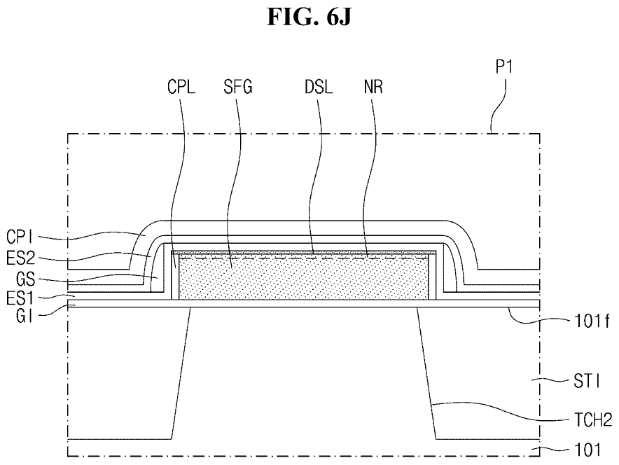

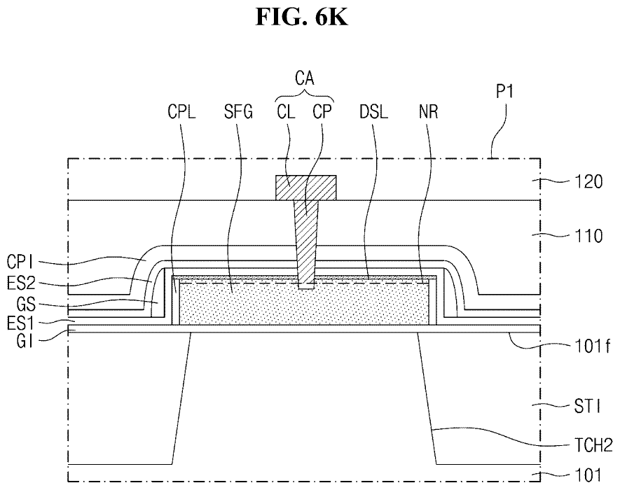

FIGS. 6A to 6K are cross-sectional views sequentially showing a fabrication method of an image sensor according to one embodiment of the present invention, and views corresponding to the region in which the source follower gate SFG of FIG. 5 is formed.

Referring to FIG. 6A, the gate insulating layer GI and the gate layer GL may be sequentially formed on the substrate 101.

The gate insulating layer GI may be formed by an oxidation process. The gate insulating layer GI may be formed by oxidizing an exposed surface of the substrate 101. In one embodiment, the oxidation process of the substrate 101 may be an in situ steam generated (ISSG) oxidation process performed under O₂ and H₂ atmospheres. In some embodiments, an in-situ nitridation process may be performed after the ISSG oxidation process, and in this case, an upper portion of the gate insulating layer GI may be nitrided, and may include a SiON.

In one embodiment, a pretreatment may be performed on the substrate 101 before forming the gate insulating layer GI. The pretreatment of the substrate 101 may be for removing a native oxide layer formed on the substrate 101. For example, the native oxide layer may be removed by wet etching using hydrofluoric acid (HF).

The gate layer GL may be formed on the gate insulating layer GI. The gate layer GL may include undoped polysilicon or may include doped polysilicon in which a group III or group V element is in-situ doped. The gate layer GL may be formed by various deposition processes, and may be formed by, for example, a low pressure chemical vapor deposition (LP-CVD) process.

When forming the gate layer GL, a di-isopropylamino silane (DIPAS) seed layer may be selectively used. The gate layer GL may be formed with various thicknesses. For example, the gate layer GL may be formed with a thickness of, for example, about 100 Å to about 2000 Å, about 200 Å to about 1500 Å, or about 400 Å to about 1300 Å.

Referring to FIG. 6B, the gate layer GL may be doped with an impurity IMP. The doping of the impurity IMP into the gate layer GL may be performed by an ion implantation process or a plasma doping (PLAD) process. The ion implantation process or the PLAD process may be performed when the gate layer GL is polysilicon that is not doped with an impurity, and may be additionally performed even when the gate layer GL is the polysilicon that is doped with the impurity IMP. The group III or group V elements may be doped as the impurity IMP of the gate layer GL.

The element to be doped may vary depending on the conductivity type of a MOS transistor, and when an N-type MOS transistor is to be formed, the group V element such as phosphorus or arsenic may be used for doping. A doping amount of the impurity IMP may vary depending on a structure of the gate to be formed, and in a case of a planar gate, the doping amount may be 1×10¹⁵/cm² (based on volume, 3×10²¹/cm³ or less in polysilicon) or more.

After doping the gate layer GL with the impurity IMP, fluorine ion implantation may be optionally performed to improve an interface trap between the gate insulating layer GI and the gate layer GL. The fluorine ion implantation may be performed at a concentration of 1×10¹⁵/cm² or more.

Referring to FIG. 6C, the diffusion barrier layer DSL may be formed on the gate layer GL. The diffusion barrier layer DSL may be formed of a silicon oxynitride (SiON).

The diffusion barrier layer DSL including the silicon oxynitride may be formed by performing a plasma nitridation process on the gate layer GL on which the natural oxide layer is present. The natural oxide layer formed on the gate layer GL may be formed of a thickness of about 10 Å or less, for example, 6 Å or less. Through the plasma nitridation process, the natural oxide layer may be transformed into a SiON layer. The plasma nitridation process may be performed in one facility, and the content of nitrogen in the diffusion barrier layer DSL may be controlled by adjusting the plasma power.

In one embodiment, the plasma nitridation process may be performed after a surface oxidation treatment of the gate layer GL. The surface oxidation treatment of the gate layer GL may be selectively performed simultaneously with a process using the natural oxide layer or as a process of replacing the natural oxide layer. The surface oxidation treatment may be a chemical oxidation process.

After the plasma nitridation process is performed, a post nitridation anneal process (hereafter, referred to as an annealing process) may be performed. The annealing process may be performed in a different chamber after the plasma treatment. The annealing process may be performed by a batch type annealing and/or a rapid thermal process (RTP), but is not limited thereto. When the annealing process is performed by the RTP, the annealing process may be performed at a temperature of about 900° C. or higher or about 1000° C. or higher for less than about one minute, less than about 30 seconds, or less than about 10 seconds. In one embodiment, the RTP annealing process may be performed at a temperature of 900° C. or higher for less than about one minute.

Since the annealing process is performed after the nitridation process is performed, nitrogen can be diffused and stabilized not only in an upper portion in the diffusion barrier layer DSL but also everywhere in the diffusion barrier layer DSL. That is, through the annealing process, the bonding of Si—O—N can be stabilized. In one embodiment, the gate insulating layer GI may also include a SiON. However, the SiON in the gate insulating layer GI may be included only in an upper portion of the gate insulating layer GI. In contrast, the SiON in the diffusion barrier layer DSL may be included not only in the upper portion of the diffusion barrier layer DSL but also everywhere in the diffusion barrier layer DSL. In one embodiment, the nitrogen in the diffusion barrier layer DSL may be substantially uniformly included throughout the entire region in the diffusion barrier layer.

The annealing process may be performed using an inert gas, and in one embodiment, N₂may be used as the inert gas. In the annealing step, optionally, an additional oxidation process of the silicon oxynitride layer may be performed by flowing O₂into the chamber for the annealing. During the additional oxidation process, the silicon oxynitride layer may be grown. A thickness of the silicon oxynitride layer may further increase by, for example, about 5 Å or less by the additional oxidation process.

In one embodiment, the diffusion barrier layer DSL after performing the plasma nitridation process and the annealing may have a thickness of about 1 Å to about 60 Å. In one embodiment, the diffusion barrier layer DSL may have a thickness of about 5 Å to about 50 Å, or a thickness of about 5 Å to about 30 Å.

When the diffusion barrier layer DSL is thinner than the above thickness, the diffusion barrier layer DSL may not adequately perform its role as the diffusion barrier layer DSL, and when the diffusion barrier layer DSL is thicker than the above thickness, it may be difficult to form a layer through the plasma nitridation process and the post nitridation anneal process. In particular, to form the diffusion barrier layer DSL having a thickness greater than the above thickness, there may be a problem that it takes so long for the plasma nitridation process and the post nitridation anneal process to be performed.

Immediately after the annealing process, bonding between nitrogen, silicon, and/or oxygen in the gate layer GL may be unstable, but nitrogen may diffuse over time and eventually, the bonding between the nitrogen, the silicon, and/or the oxygen may be stabilized. Accordingly, a nitrogen content ratio in the gate layer GL may be stably maintained.

In one embodiment, since the diffusion barrier layer DSL is formed using the plasma nitridation process and the annealing process, the nitrogen may also penetrate and/or diffuse into the upper portion of the gate layer GL. Accordingly, when forming the diffusion barrier layer DSL, the nitrogen-rich gate region NR may also be formed in the upper portion of the gate layer GL. Here, the upper portion of the gate layer GL may correspond to a predetermined region extending in the depth direction from the interface between the diffusion barrier layer DSL and the gate layer GL. When a silicon oxynitride is formed on the upper portion of the gate layer GL using a deposition method such as LP-CVD, there is substantially no penetration and/or diffusion of nitrogen into the gate layer GL.

Referring to FIG. 6D, the gate layer GL may be patterned to form gates of pixel transistors, including the source follower gate SFG. Although not shown, the gate layer GL may be patterned to also form a reset gate, a selection gate, and/or a transfer gate. The gates of the pixel transistors may be formed to correspond to a shape and a size of a transistor to be manufactured using a process such as photolithography. For example, the gates of pixel transistors may be formed by forming a photoresist on the gate layer GL, performing exposure and development, and etching a partial region of the gate layer GL. Hereinafter, as shown, the source follower gate SFG among the gates of the pixel transistors will be described as an example.

Referring to FIG. 6E, the capping liner CPL may be formed on both side surfaces of the source follower gate SFG. When forming the source follower gate SFG, the both side surfaces of the source follower gate SFG may be damaged due to an etching process. A process of forming the capping liner CPL may correspond to a process of recovering the damaged both side surfaces of the source follower gate SFG. The capping liner CPL may be formed by oxidizing the source follower gate SFG. During the oxidation process of the source follower gate SFG, only the both side surfaces of the source follower gate SFG may be oxidized, and the upper surface of the source follower gate SFG may not be oxidized because the diffusion barrier layer DSL is provided on the upper surface of the source follower gate SFG. A silicon oxide layer may grow inward from the exposed both side surfaces of the source follower gate SFG by an oxidation reaction. Some polysilicon may be lost due to the oxidation reaction, but the polysilicon of upper surface of the source follower gate SFG may remain. As a result, the capping liner CPL is formed on the both side surfaces of the source follower gate SFG, and the upper surface of the capping liner CPL may come into contact with the lower surface of the diffusion barrier layer DSL.

Referring to FIG. 6F, the first etching stop layer ES1 may be disposed on the first surface 101f of the substrate 101 to conformally cover the source follower gate SFG and the gate insulating layer GI.

The first etching stop layer ES1 may correspond to a layer for preventing additional etching when performing an etching process to form the gate spacer GS described below. The first etching stop layer ES1 may be selected from materials with high etching selectivity with respect to a material constituting the gate spacer GS. In one embodiment, the first etching stop layer ES1 may include a silicon oxide. The first etching stop layer ES1 may be formed through various processes, and may be formed using, for example, a chemical vapor deposition (CVD) process. The first etching stop layer ES1 may be formed with various thicknesses and formed, for example, about 50 Å or less.

Referring to FIG. 6G, a spacer insulating layer GSL may be formed on the first etching stop layer ES1.

The spacer insulating layer GSL may be selected from materials different from that of the first etching stop layer ES1, for example, materials with high etching selectivity with respect to the first etching stop layer ES1. In one embodiment, the spacer insulating layer GSL may include silicon nitride and/or silicon oxynitride. The spacer insulating layer GSL may be formed through various processes, and may be formed using, for example, the LP-CVD process at a temperature of about 700° C. or less.

Although not shown, after forming the source follower gate SFG, a process of implanting an impurity may be performed into the active region, and s source/drain may be formed in a portion of the active region adjacent to the source follower gate SFG.

Referring to FIG. 6H, the spacer insulating layer GSL may be etched to form the gate spacer GS. When the spacer insulating layer GSL is etched, the spacer insulating layer GSL on the upper surface of the source follower gate SFG may be removed by being etched, and only the spacer insulating layer GSL on the both side surfaces of the source follower gate SFG may remain to form the gate spacers GS.

Referring to FIGS. 6I and 6J, the second etching stop layer ES2 and the capping insulating layer CPI may be sequentially formed on the substrate 101. The second etching stop layer ES2 may conformally cover the gate insulating layer GI, the diffusion barrier layer DSL, and the gate spacer GS, and the capping insulating layer CPI may conformally cover the second etching stop layer ES2.

In one embodiment, the second etching stop layer ES2 may include a silicon oxide. The second etching stop layer ES2 may be formed through various processes and may be formed using, for example, the CVD process.

The capping insulating layer CPI may be selected from materials different from that of the second etching stop layer ES2, for example, materials with high etching selectivity with respect to the second etching stop layer ES2. In one embodiment, the capping insulating layer CPI may include a silicon nitride. The capping insulating layer CPI may be formed through various processes, and may be formed using, for example, the LPCVD process at about 700° C. or less or the plasma nitridation process.

Referring to FIG. 6K, the first interlayer insulating layer 110 may be disposed on the first surface 101f of the substrate 101 to cover the capping insulating layer CPI.

The first interlayer insulating layer 110 may include various insulating materials and may be formed using various processes. For example, the first interlayer insulating layer 110 may include tetra ethyl ortho silicate TEOS and may be formed using the CVD process.

Various lines may be formed on the first interlayer insulating layer 110. The various lines may include the contact complex CA and the line pattern LP, and as an example, the contact complex CA may be formed on the source follower gate SFG. The contact complex CA may include the contact plug CP penetrating through the first interlayer insulating layer 110, the second etching stop layer ES2, the first etching stop layer ES1, and the diffusion barrier layer DSL to come into contact with the source follower gate SFG and the contact line CL formed on the first interlayer insulating layer 110. The contact complex CA may be formed through a process of forming a contact hole penetrating through the first interlayer insulating layer 110, the second etching stop layer ES2, the first etching stop layer ES1, and the diffusion barrier layer DSL and filling the contact hole with a conductive material. However, the process of forming the contact complex CA is not limited thereto, and it goes without saying that other various processes of forming a conductive line may be used.

According to one embodiment of the present invention, the presence or absence of the diffusion barrier layer may affect the performance of the pixel transistors in addition to the source follower transistor. This is described as follows.

In a case of an embodiment in which the diffusion barrier layer is not formed, a surface of the polysilicon constituting the gate layer of the pixel transistor may be exposed to a high-temperature oxidation process after impurity ion implantation. The surface of the polysilicon may undergo the oxidation process to form a silicon oxide capping layer. Since the silicon oxide capping layer is formed by oxidizing a portion of the polysilicon constituting the gate layer, the loss of the polysilicon may be inevitable. For example, polysilicon with a thickness of about 105 Å may be used to form a silicon oxide layer with a thickness of about 240 Å. In addition, the silicon oxide capping layer is a layer containing a large amount of impurities of the gate layer and may be removed by etching of a silicon oxide later, and in this case, there is a problem that the impurities of the gate layer may also be removed along with the silicon oxide during the etching of the silicon oxide. Accordingly, there is a problem that the sheet resistance of a source follower gate SFG layer increases and the depletion characteristics deteriorate.

In contrast, in one embodiment of the present invention, since a diffusion barrier layer is provided on an upper surface of a gate, it is possible to prevent an oxidation reaction in the upper surface of the gate, thereby preventing or minimizing the loss of polysilicon of the gate. In addition, since the impurity in the gate can be maintained without any loss, it is possible to decrease the sheet resistance and improve the depletion characteristics of the source follower gate.

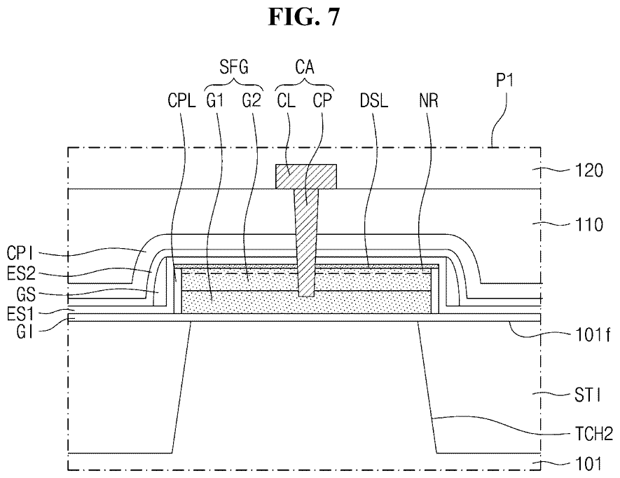

FIG. 7 is an enlarged cross-sectional view showing a region in which a source follower gate is formed in an image sensor according to one embodiment of the present invention and is an enlarged view corresponding to portion P1 of FIG. 4A. In the following embodiments, differences from the above described embodiments will be mainly described in order to avoid duplication of explanation.

Referring to FIG. 7, the source follower gate SFG may be provided as a double layer. In other words, the source follower gate SFG may include a lower gate G1 disposed on the gate insulating layer GI and an upper gate G2 disposed on the lower gate G1. A natural oxide layer may be interposed between the lower gate G1 and the upper gate G2.

Thicknesses of the lower gate G1 and the upper gate G2 may be the same. However, the thicknesses of the lower gate G1 and the upper gate G2 may vary, and the thickness of one of the lower gate G1 and the upper gate G2 may be about 90% or more of the thickness of the other. In one embodiment, the thickness of the upper gate G2 may have a value equal to or larger than the thickness of the lower gate G1.

When the source follower gate SFG includes the lower gate G1 and the upper gate G2, since impurities may be implanted into each of the lower gate G1 and the upper gate G2, the concentration of the impurities can be maintained high throughout the source follower gate SFG, and the uniformity of distribution of the impurities can also be secured.

The diffusion barrier layer DSL may be provided on the source follower gate SFG, specifically on an upper surface of the upper gate G2.

The capping liner CPL may be provided on both side surfaces of the source follower gate SFG. Specifically, the capping liner CPL may be provided on both side surfaces of the lower gate G1 and on both side surfaces of the upper gate G2. The capping liner CPL formed on the both side surfaces of each of the upper gate G2 and the lower gate G1 may be formed as a single body without separation.

The first etching stop layer ES1, the gate spacer GS, the second etching stop layer ES2, and the capping insulating layer CPI may be provided on the diffusion barrier layer DSL. The first interlayer insulating layer 110 may be provided on the capping insulating layer CPI. The contact complex CA may be provided in and on the first interlayer insulating layer 110.

The contact complex CA may include the contact plug CP penetrating through the first interlayer insulating layer 110, the second etching stop layer ES2, the first etching stop layer ES1, and the diffusion barrier layer DSL to come into contact with the source follower gate SFG and the contact line CL formed on the first interlayer insulating layer 110. In the present embodiment, the contact plug CP may penetrate through the upper gate G2 and extend to the lower gate G1. Accordingly, the contact plug CP may be electrically connected to the lower gate G1.

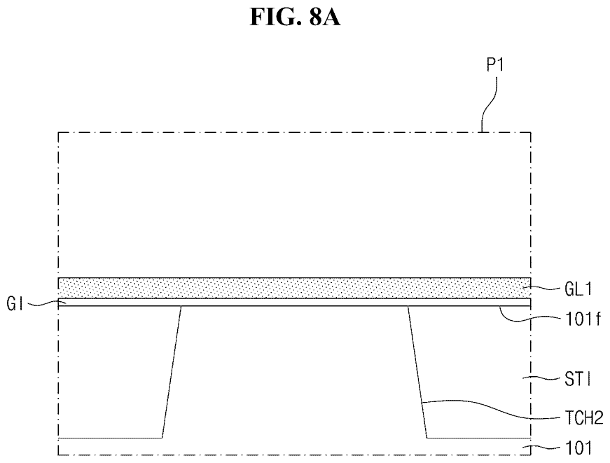

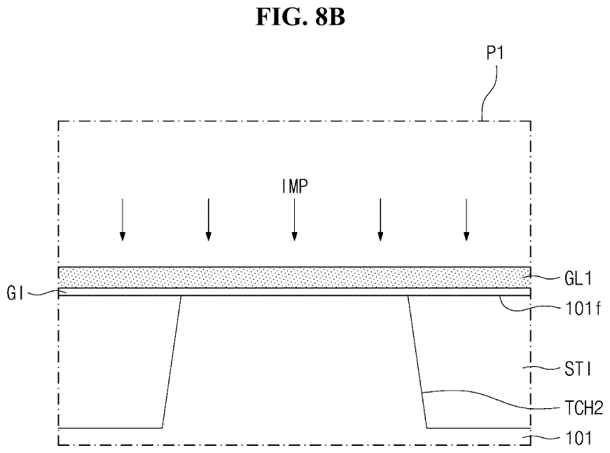

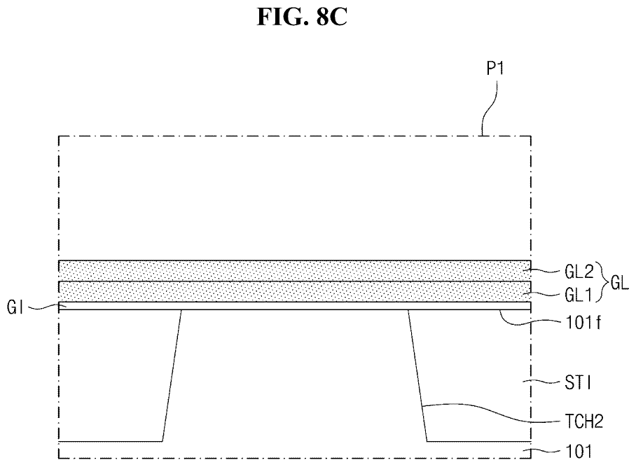

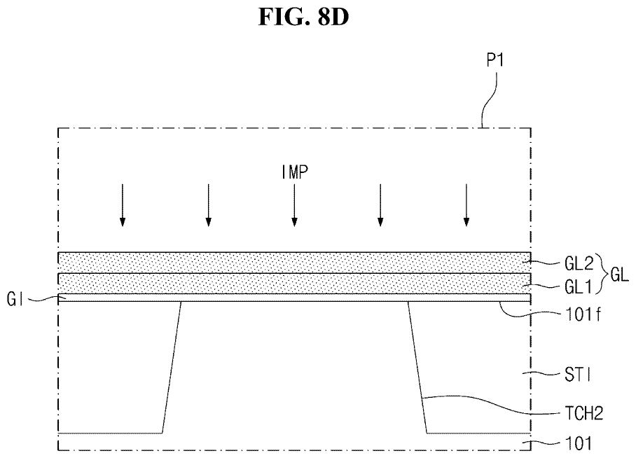

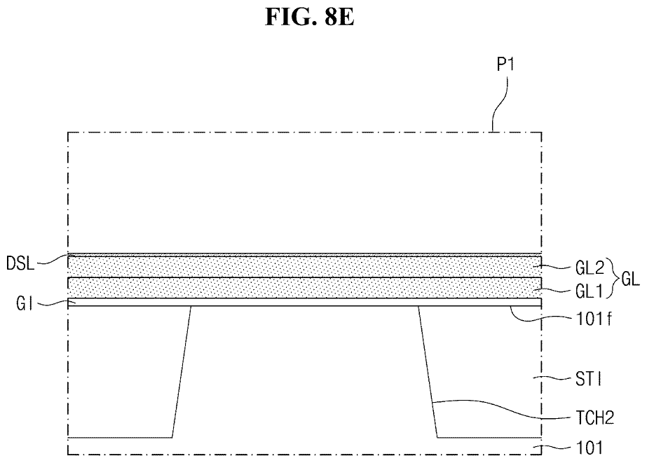

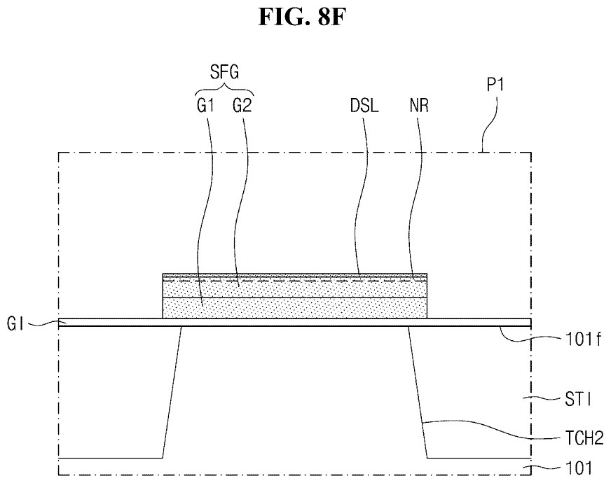

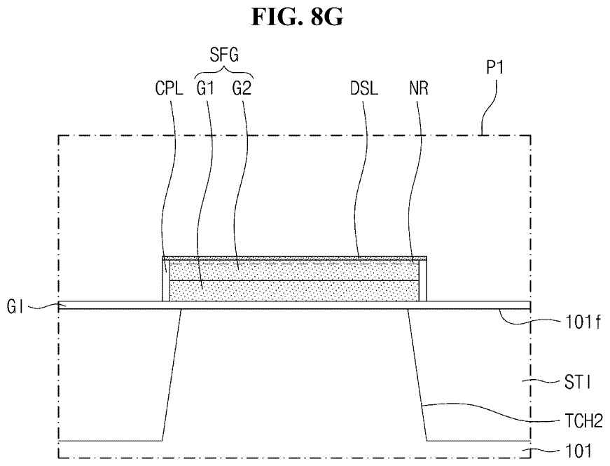

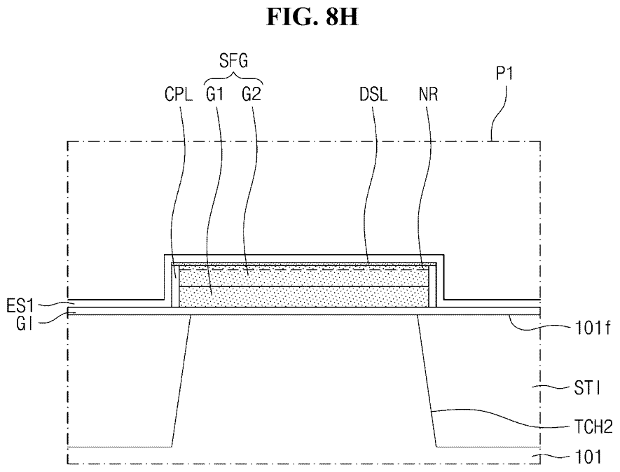

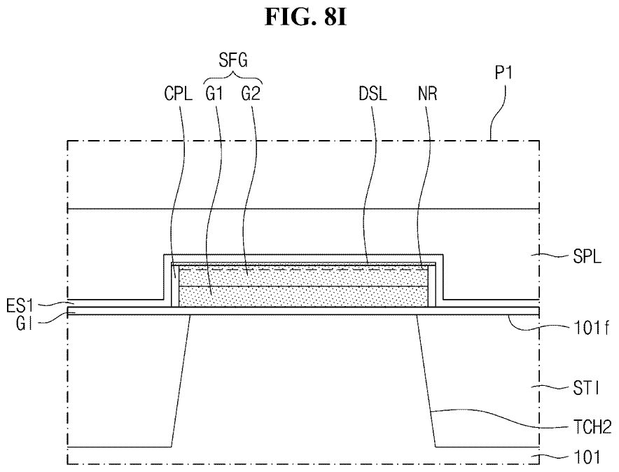

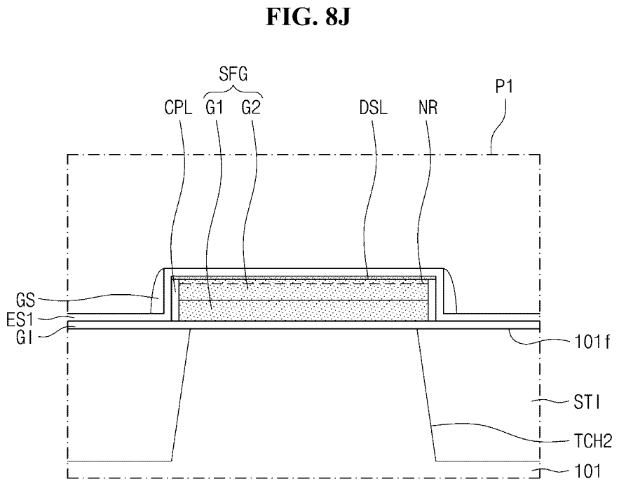

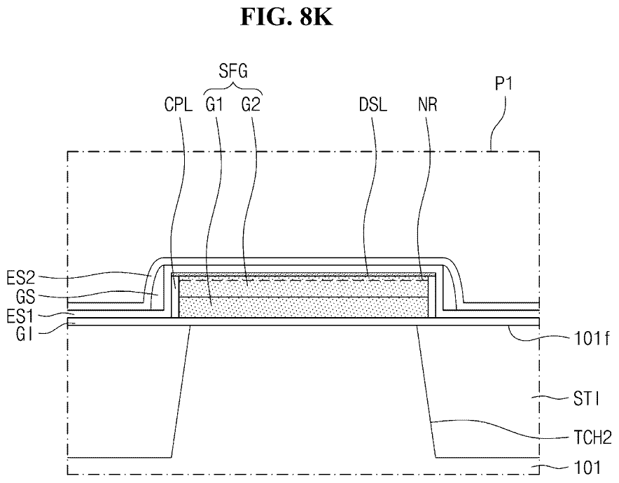

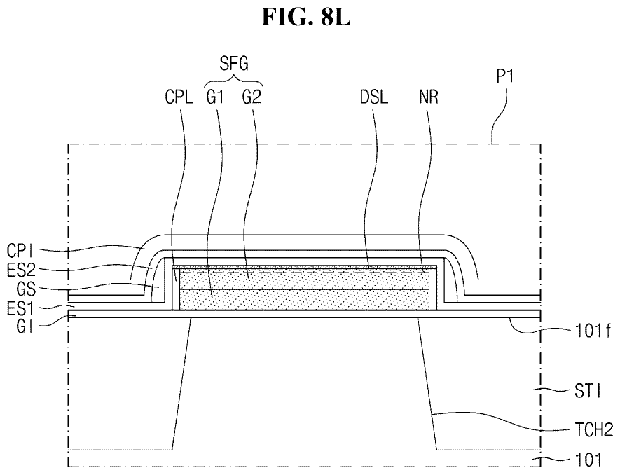

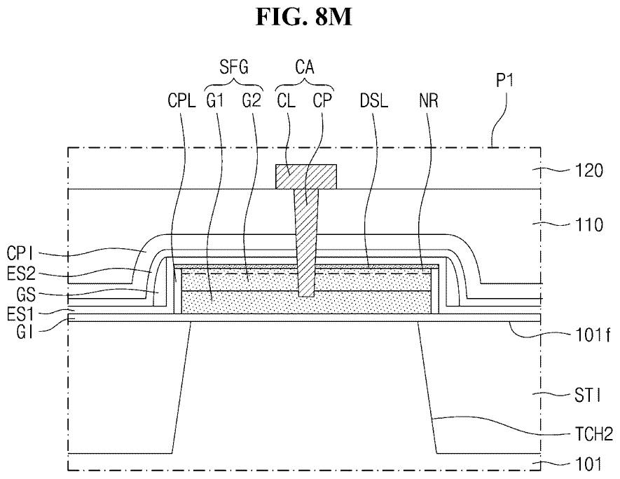

FIGS. 8A to 8M are cross-sectional views sequentially showing a fabrication method of an image sensor according to one embodiment of the present invention, and views corresponding to the region in which the source follower gate SFG of FIG. 7 is formed.

Referring to FIG. 8A, the gate insulating layer GI and a lower gate layer GL1 may be sequentially formed on the substrate 101.

The lower gate layer GL1 may be formed on the gate insulating layer GI. The lower gate layer GL1 may include undoped polysilicon or may include doped polysilicon in which a group III or group V element is in-situ doped. The lower gate layer GL1 may be formed by various deposition processes, and may be formed by, for example, a low pressure chemical vapor deposition (LP-CVD) process. When forming the lower gate layer GL1, a di-isopropylamino silane (DIPAS) seed layer may be selectively used.

Referring to FIG. 8B, the lower gate layer GL1 may be doped with an impurity IMP. The doping of the impurity IMP into the lower gate layer GL1 may be performed by an ion implantation process or a plasma doping (PLAD) process. The ion implantation process or the PLAD process may be performed when the lower gate layer GL1 is formed of polysilicon that is not doped with an impurity IMP, and may be additionally performed even when the lower gate layer GL1 is formed of the polysilicon that is doped with the impurity IMP. The group III or group V elements may be doped as the impurity IMP of the lower gate layer GL1.

Referring to FIG. 8C, an upper gate layer GL2 may be formed on the lower gate layer GL1.

The upper gate layer GL2 may be made of the same material as the lower gate layer GL1, but is not limited thereto. For example, the upper gate layer G2 may include undoped polysilicon or may include doped polysilicon in which a group III or group V element is in-situ doped. The upper gate layer GL2 may be formed by various deposition processes, and may be formed by, for example, the LP-CVD process. When forming the upper gate layer GL2, a DIPAS seed layer may be selectively used.

Referring to FIG. 8D, the upper gate layer GL2 may be doped with an impurity IMP. The doping of the impurity IMP into the upper gate layer GL2 may be performed by the ion implantation process or the PLAD process. The ion implantation process or the PLAD process may be performed when the upper gate layer GL2 is polysilicon that is not doped with an impurity IMP, and may be additionally performed even when the upper gate layer GL2 is the polysilicon that is doped with the impurity IMP. The group III or group V elements may be doped as the impurity IMP of the upper gate layer GL2. The impurity IMP used for the upper gate layer GL2 may be the same as the impurity IMP used for the lower gate layer GL1, but is not limited thereto.

In FIGS. 8A to 8M, FIGS. 8E to 8L are not substantially different from FIGS. 6C to 6J except that the source follower gate SFG is formed as a double layer, so the description will be omitted. Here, the diffusion barrier layer DSL may be formed on the upper gate G2.

Referring to FIG. 8M, the contact complex CA may be formed in and on the first interlayer insulating layer 110. The contact complex CA may include the contact plug CP penetrating through the first interlayer insulating layer 110, the second etching stop layer ES2, the first etching stop layer ES1, and the diffusion barrier layer DSL to come into contact with the source follower gate SFG and the contact line CL formed on the first interlayer insulating layer 110. The contact complex CA may be formed a process of forming a contact hole penetrating through the first interlayer insulating layer 110, the second etching stop layer ES2, the first etching stop layer ES1, the diffusion barrier layer DSL, and the upper gate G2 and filling the contact hole with a conductive material. In one example, the contact hole may be formed to further penetrate into the lower gate layer G1, and in this case, the contact complex CA, formed by filling the contact hole with the conductive material, may be in contact with the lower gate layer G1. However, the process of forming the contact complex CA is not limited thereto, and it goes without saying that other various processes of forming a conductive line may be used.

In a different embodiment from the present invention, when manufacturing an image sensor with a double layer of a source follower gate without forming a diffusion barrier layer, there may be the following problems.

In order to form the double layer of the source follower gate, forming a lower gate, implanting an impurity, forming an upper gate, and implanting an impurity may be performed. However, a process of forming the upper gate and implanting the impurity may be performed after forming a silicon oxide capping layer. In this case, since a thickness of the silicon oxide capping layer is large, the amount of the impurity implanted into the upper gate may be very small, that is, about 3%. In addition, an impurity level of the source follower gate may be substantially determined by the impurity implantation process of the lower gate. The impurity implantation process of the upper gate may serve to weaken the wet etching resistance of the silicon oxide capping layer and accordingly, the silicon oxide capping layer may be easily removed. After the silicon oxide capping layer is removed, a source follower gate layer may be patterned, and an oxidation process for recovering damage caused by the patterning may be performed. In this case, the source follower gate layer may undergo an oxidation reaction on an upper surface and side surfaces thereof that are exposed externally, and the loss of polysilicon and the impurity that constitute the source follower gate layer may simultaneously occur.

In contrast, according to one embodiment of the present invention, when the source follower gate SFG is formed, the lower gate layer GL1 and the upper gate layer GL2 are each formed, and by implanting the impurity into each gate layer GL and forming the diffusion barrier layer DSL on the upper gate layer GL2, the loss of polysilicon and the impurity that constitute the gate layer GL can be prevented. By preventing the loss of the polysilicon and the impurity, the concentration of the impurity can be improved or maximized, and eventually the sheet resistance and trans-conductance of the source follower gate SFG can be improved.

In the above-described embodiments, the source follower gate may have other various structures other than the above-described structure.

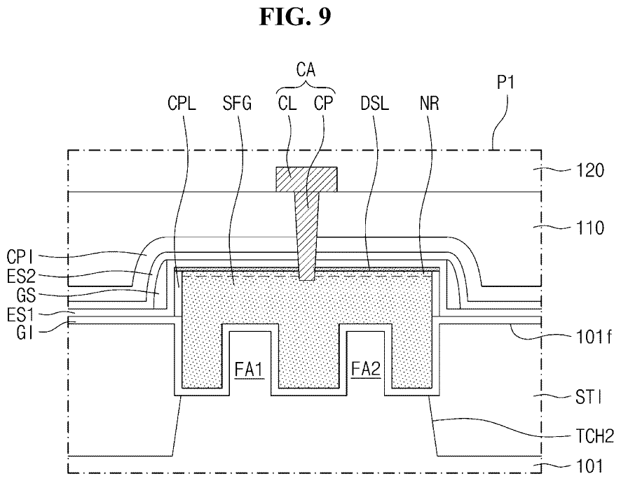

FIG. 9 is an enlarged cross-sectional view showing a region in which a source follower gate is formed in an image sensor according to one embodiment of the present invention and is an enlarged view corresponding to portion P1 of FIG. 4A.

Referring to FIG. 9, the source follower gate SFG may be a portion of a fin field effect transistor (finFET) transistor having a fin structure. The source follower gate SFG may be disposed on a first fin-type active region FA1 and a second fin-type active region FA2.

The gate may include a horizontal extending portion provided on an upper surface of the substrate 101 and vertical extending portions extending in the depth direction of the substrate 101. In one embodiment of the present invention, the number of vertical extending portions may be three, but are not limited thereto and may be two, four, or more. The first and second fin-type active regions FA1 and FA2 may correspond to regions between the vertical extending portions extending into the inside of the substrate 101.

In one example, since the source follower transistor SFG has the fin structure, even when a size of the source follower transistor is small, a relatively large effective gate width can be secured and a control capability of the gate for a channel can be improved, thereby reducing read noise and reducing a leakage current of the source follower transistor.

In the above-described embodiments, the diffusion barrier layer DSL, which is applied to a gate of a planar transistor, has been shown, but is not limited thereto. The diffusion barrier layer DSL may also be applied to gates of other types of transistors.

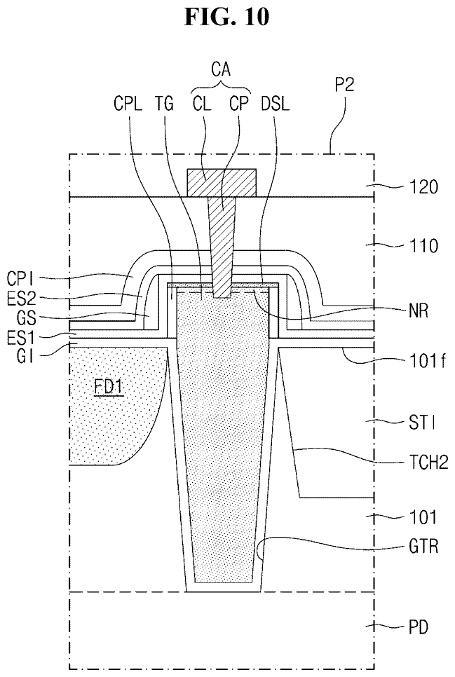

FIG. 10 is an enlarged cross-sectional view showing a region in which the transfer gate TG is formed in an image sensor according to one embodiment of the present invention and is a view corresponding to portion P2 of FIG. 4A.

Referring to FIG. 10, the diffusion barrier layer DSL may also be applied to a vertical type of the transfer gate TG. The transfer gate TG may be disposed inside a gate trench GTR extending from the first surface 101f of the substrate 101 into the inside of the substrate 101. The gate insulating layer GI may be conformally disposed on an inner wall of the gate trench GTR, and the buried transfer gate TG may fill the inside of the gate trench GTR on the gate insulating layer GI.

In one embodiment, an upper surface of the transfer gate TG may be disposed at a level higher than the first surface 101f of the substrate 101.

The diffusion barrier layer DSL may be provided on the transfer gate TG.

The capping liner CPL may be provided on both side surfaces of the transfer gate TG.

The first etching stop layer ES1, the gate spacer GS, the second etching stop layer ES2, and the capping insulating layer CPI may be provided on the diffusion barrier layer DSL. The first interlayer insulating layer 110 may be provided on the capping insulating layer CPI. The contact complex CA may be provided in and on the first interlayer insulating layer 110.

The contact complex CA may include the contact plug CP penetrating through the first interlayer insulating layer 110, the second etching stop layer ES2, the first etching stop layer ES1, and the diffusion barrier layer DSL to come into contact with the transfer gate TG and the contact line CL formed on the first interlayer insulating layer 110.

In one embodiment of the present invention, the transfer gate may be formed of a vertical type and the source follower gate, the selection gate, and the reset gate may be formed of planar types, but the present invention is not limited thereto, and at least some gates may be formed of the planar types or at least some gates may be formed of the vertical types.

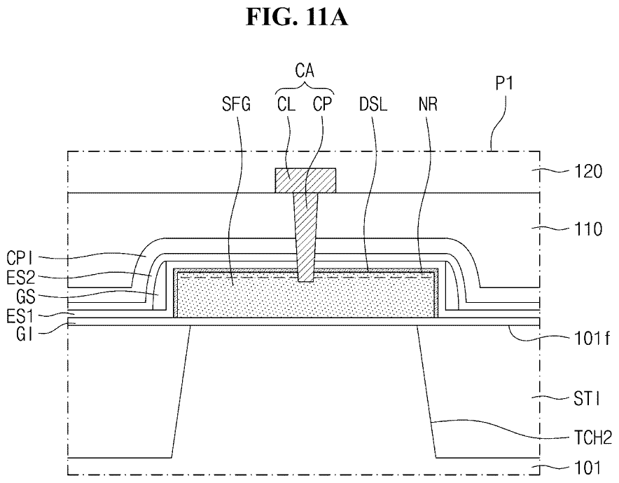

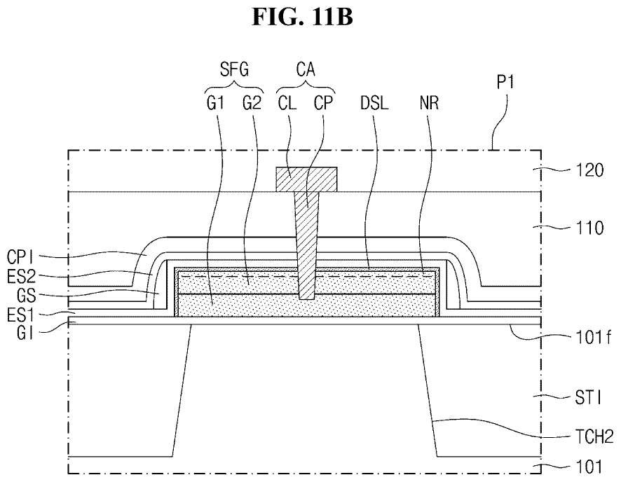

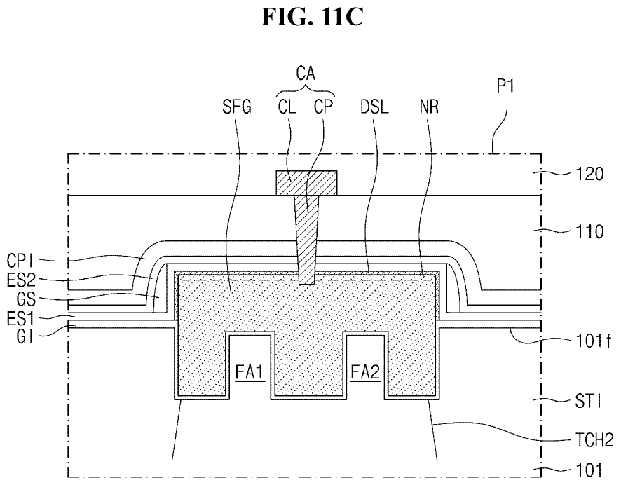

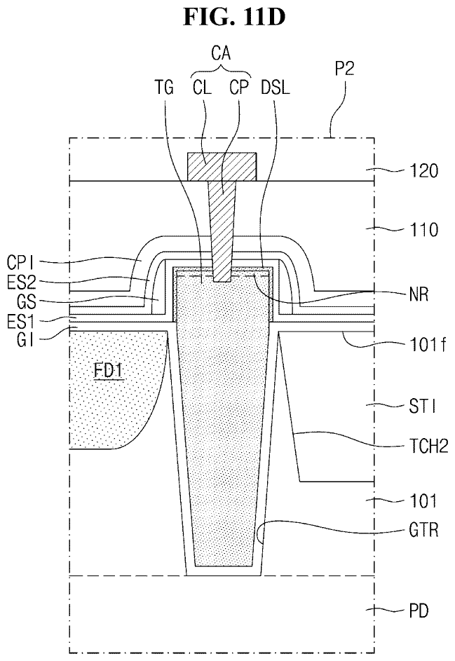

FIGS. 11A to 11D are enlarged cross-sectional views showing regions in which gates of pixel transistors are formed in an image sensor according to one embodiment of the present invention. FIGS. 11A to 11C are views corresponding to the P1 portion of FIG. 4A, and FIG. 11D is a view corresponding to the P2 portion of FIG. 4A.

Referring to FIGS. 11A to 11D, the source follower gate SFG and the transfer gate TG are shown as examples in FIGS. 11A to 11D, and the diffusion barrier layer DSL may be provided on upper surfaces of the gates of the pixel transistors. In addition, the diffusion barrier layer DSL may also be provided on both side surfaces of each gate. The capping liner CPL may not be provided on the both side surfaces of each gate, and the diffusion barrier layer DSL instead of the capping liner CPL may be provided on the both side surfaces of each gate.

The diffusion barrier layer DSL on the both side surfaces of each gate may be formed by performing the plasma nitridation process on both side walls of each gate after patterning the gate layer GL. Since the diffusion barrier layer DSL is formed not only on the upper surface but also on the both side surfaces of each gate, the loss of polysilicon and the impurity inside the polysilicon that are included in each gate can be prevented or minimized.

According to one embodiment of the present invention, the gate characteristics of pixel transistors can be improved by forming a diffusion barrier layer on gates of the pixel transistors. Accordingly, an image element with improved performance can be provided.

Although the present invention has been described above with reference to preferred embodiments, it will be understood that those skilled in the art or those having ordinary knowledge in the art can modify and change the present invention in various ways within the scope without departing from the spirit and technical area of the present invention as set forth in the claims described below.

Therefore, the technical scope of the present invention should not be limited to what is described in the detailed description of the specification but should be determined by the claims.

What is claimed is:

1. An image sensor comprising:
a substrate;
a gate insulating layer on the substrate;
at least one gate on the gate insulating layer;
a diffusion barrier layer on an upper surface of the at least one gate and including a silicon oxynitride; and
a capping insulating layer on the diffusion barrier layer, and
wherein
the gate includes a nitrogen-rich gate region adjacent to the upper surface of the gate therein, and the nitrogen-rich gate region has a higher content of nitrogen than the remaining region in the gate excluding the nitrogen-rich gate region.

2. The image sensor of claim 1, wherein
the diffusion barrier layer has a thickness of 1 Å to 60 Å.

3. The image sensor of claim 1, wherein
the gate includes doped polysilicon.

4. The image sensor of claim 1, further comprising
an etching stop layer between the diffusion barrier layer and the capping insulating layer,
wherein the etching stop layer includes a silicon oxide and the capping insulating layer includes a silicon nitride.

5. The image sensor of claim 1, further comprising
a capping liner on both side surfaces of the at least one gate in a cross-sectional view.

6. The image sensor of claim 1, wherein
the diffusion barrier layer extends onto both side surfaces of the at least one gate in a cross-sectional view.

7. The image sensor of claim 1, further comprising:
a deep isolation pattern penetrating through the substrate;
a shallow isolation pattern defining an active region; and
at least one pixel transistor in and/or on the active region, and
wherein
the at least one gate is a gate of the at least one pixel transistor.

8. The image sensor of claim 7, wherein
the at least one pixel transistor includes a transfer transistor, a source follower transistor, a selection transistor, and a reset transistor, and
the at least one gate is at least one among gates of the transfer transistor, the source follower transistor, the selection transistor, and the reset transistor.

9. The image sensor of claim 8, wherein
the gate of the transfer transistor is provided in a vertical type, and the gates of the source follower transistor, the selection transistor, and the reset transistor are provided in a planar type.

10. The image sensor of claim 7, wherein
the at least one pixel transistor is a fin field effect transistor (finFET).

11. The image sensor of claim 1, wherein
the at least one gate includes a lower gate on the gate insulating layer and an upper gate on the lower gate.

12. An image sensor comprising:
a substrate having a first surface and a second surface opposite to the first surface;
a deep isolation pattern penetrating through the substrate;
a shallow isolation pattern disposed adjacent to the first surface;
a floating diffusion region disposed in the active region;
a source follower gate disposed on the active region;
a diffusion barrier layer on the source follower gate and including a silicon oxynitride; and
a capping insulating layer on the diffusion barrier layer, and
wherein
the diffusion barrier layer has a thickness of 1 Å to 60 Å.

13. The image sensor of claim 12, wherein
the source follower gate includes a nitrogen-rich gate region adjacent to an upper surface of the source follower gate therein, and the nitrogen-rich gate region has a higher content of nitrogen than the remaining region in the source follower gate excluding the nitrogen-rich gate region.

14. The image sensor of claim 12, further comprising
an etching stop layer between the diffusion barrier layer and the capping insulating layer,
wherein the etching stop layer includes a silicon oxide, and the capping insulating layer includes a silicon nitride.

15. An image sensor comprising:
a substrate;
a gate insulating layer disposed on the substrate;
a gate disposed on the gate insulating layer and including a nitrogen-rich gate region having a higher content of nitrogen than another region in the gate;
a diffusion barrier layer disposed on the gate and including a silicon oxynitride; and
a capping insulating layer disposed on the diffusion barrier layer; and
a contact plug penetrating through the capping insulating layer, the diffusion barrier layer, and the nitrogen-rich gate region.

16. The image sensor of claim 15, further comprising
an etching stop layer between the diffusion barrier layer and the capping insulating layer,
wherein the etching stop layer includes a silicon oxide and the capping insulating layer includes a silicon nitride, and
the contact plug also penetrates through the etching stop layer.

17. The image sensor of claim 15, wherein
the contact plug penetrates in the another region in the gate having a lower content of nitrogen than the nitrogen-rich gate region.

18. The image sensor of claim 15, wherein
the gate includes a lower gate on the gate insulating layer and an upper gate on the lower gate, and
the contact plug penetrates in the lower gate.

19. The image sensor of claim 15, wherein
the gate includes doped polysilicon.

20. The image sensor of claim 15, wherein
the diffusion barrier layer extends onto side surfaces of the gate.
